(19) United States
(12) Patent Application Publication
(10) Pub. No.: US 2010/0023294 A1
(43) Pub. Date: Jan. 28, 2010

(54) AUTOMATED TEST SYSTEM AND METHOD

(75) Inventors: Yung Daniel Fan, Los Altos, CA (US); David N. Grant, Cupertino, CA (US); Mark Hanbury Brown, Wimborne (GB); Jonathan David Godfree Pryce, Broadstone (GB)

Correspondence Address: CREDENCE C/O MURABITO HAO BARNES, LLP, TWO NORTH MARKET STREET, THIRD FLOOR, SAN JOSE, CA, 95113, US

(73) Assignee: CREDENCE SYSTEMS CORPORATION, Milpitas, CA (US)

(21) Appl. No.: 12/200,801

(22) Filed: Aug. 28, 2008

Related U.S. Application Data
(60) Provisional application No. 61/084,235, filed on Jul. 28, 2008.

(51) Int. Cl. G01R 31/28

(52) U.S. Cl. 702/123

(57) ABSTRACT

An efficient automated testing system and method are presented. In one embodiment, an automated testing system includes a control component and an automated test instrument for testing a device or a plurality of devices (e.g., packages or wafers containing multiple independent different devices) under test. The automated test instrument component performs testing operation on the device or devices under test (DUT). The control component manages testing activities of a test instrument testing the device under test, including managing implementation of a plurality of test programs loaded as a group. In one exemplary implementation, the automated test system also includes a DUT interface and a user interface. The device under test interface interfaces with a device or devices under test.

### RELATED APPLICATIONS

The present Application claims the benefit of and priority to the US Provisional Application entitled “AN AUTOMATED TEST SYSTEM AND METHOD”, Application No. 61/084235, Attorney Docket Number CRDC-809.PRO filed Jul. 28, 2008, which is incorporated herein by this reference.

### FIELD OF THE INVENTION

The present invention relates to the field of automated test equipment.

### BACKGROUND OF THE INVENTION

Electronic and optical systems have made a significant contribution towards the advancement of modern society and are utilized in a number of applications to achieve advantageous results. Numerous electronic technologies such as digital computers, calculators, audio devices, video equipment, and telephone systems have facilitated increased productivity and reduced costs in analyzing and communicating data in most areas of business, science, education and entertainment. Electronic systems providing these advantageous results are often complex and are tested to ensure proper performance. However, traditional approaches to automated testing can be relatively time consuming and expensive.

Generally, the speed at which a testing is performed can have a significant impact on the cost of testing. Some Multi-Chip Module (MCM) and System-In-Package (SIP) applications have multiple devices under test (DUTs) in the same package that performs their tasks independently. Some Multi-Chip Wafer (MCW) applications have different DUTs on the same ASIC wafer. Typical Package-on-Package (PoP) applications can support multiple DUTs stacked together for system integration. There are other applications that have different DUTs on the same ASIC wafer. These situations often involve a user performing multiple pass testing to test the different DUTs with different test programs or creating a new test program that comprehends the testing of the different DUTs. The first approach can impact the test production throughput, while the second practice consumes engineering resources and creates correlation issues. Some conventional approaches have attempted to concurrently test multiple intellectual property (IP) blocks within each device. However, these attempts do not typically address testing different devices utilizing different test programs.

### SUMMARY

An efficient automated testing system and method are presented. In one embodiment, an automated testing system includes a control component and an automated test instrument for testing a device or a plurality of devices (e.g., packages or wafers containing multiple independent different devices) under test. The automated test instrument component performs testing operation on the device or devices under test (DUT). The control component manages testing activities of a test instrument testing the device under test, including managing implementation of a plurality of test programs loaded as a group. In one exemplary implementation, the automated test system also includes a DUT interface and a user interface. The device under test interface interfaces with a device or devices under test.

### DESCRIPTION OF THE DRAWINGS

The accompanying drawings, which are incorporated in and form a part of this specification, illustrate embodiments of the invention by way of example and not by way of limitation. The drawings referred to in this specification should be understood as not being drawn to scale except if specifically noted.

FIG. 1 is a block diagram of an exemplary automated testing environment in accordance with one embodiment of the present invention.

FIG. 2 is a block diagram of an exemplary automated testing system in accordance with one embodiment of the present invention.

FIG. 3 is a block diagram of exemplary multi-test program components in accordance with one embodiment of the present invention.

FIG. 4 is a flow chart of an exemplary testing method in accordance with one embodiment of the present invention.

FIG. 5 is a block diagram of exemplary multiple device types in die layouts on a wafer in accordance with one embodiment of the present invention.

FIG. 6 is an exemplary block diagram illustrating exemplary principle users of a management class in accordance with one embodiment of the present invention.

FIG. 7 is a block diagram of a portion of an exemplary software framework in accordance with one embodiment of the present invention.

### DETAILED DESCRIPTION

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the present invention, numerous specific details are set forth in order to provide a thorough understanding of the present invention. However, it will be obvious to one of ordinary skill in the art that the present invention may be practiced without these specific details. In other instances, well known methods, procedures, components, and circuits have not been described in detail as not to unnecessarily obscure aspects of the present invention.

Some portions of the detailed descriptions which follow are presented in terms of procedures, logic blocks, processing, and other symbolic representations of operations on data bits within a computer memory. These descriptions and representations are the means generally used by those skilled in data processing arts to effectively convey the substance of their work to others skilled in the art. A procedure, logic block, process, etc., is here, and generally, conceived to be a self-consistent sequence of steps or instructions leading to a desired result. The steps include physical manipulations of physical quantities. Usually, though not necessarily, these quantities take the form of electrical, magnetic, optical, or quantum signals capable of being stored, transferred, combined, compared, and otherwise manipulated in a computer system. It has proven convenient at times, principally for reasons of common usage, to refer to these signals as bits, values, elements, symbols, characters, terms, numbers, or the like.

It should be borne in mind, however, that all of these and similar terms are associated with the appropriate physical quantities and are merely convenient labels applied to these quantities. Unless specifically stated otherwise as apparent from the following discussions, it is appreciated that throughout the present application, discussions utilizing terms such as “processing”, “computing”, “calculating” “determining”, “displaying” or the like, refer to the action and processes of a computer system, or similar processing device (e.g., an electrical, optical, or quantum, computing device) that manipulates and transforms data represented as physical (e.g., electronic) quantities. The terms refer to actions and processes of the processing devices that manipulate or transform physical quantities within a computer system's component (e.g., registers, memories, other such information storage, transmission or display devices, etc.) into other data similarly represented as physical quantities within other components.

Present invention automated testing equipment systems and methods facilitate efficient and effective testing. In one embodiment of the present invention, multi-test program systems and methods facilitate coordinated utilization of separately developed and maintained test programs (e.g., one for each of a plurality of building blocks of components or intellectual property blocks) as a single program without manually rewriting the separately developed and maintained test programs. In one embodiment, an additional hierarchy is added to allow specification of multiple test programs to be executed together.

In one embodiment, the additional hierarchy includes support for a plurality of test programs loaded at a single load time as a single container for device test of multiple chip modules, packages and wafers. The automated test system can also support a variety of applications including system-in-package, multi-chip-module testing, multi-chip wafer testing and concurrent diagnostic testing. In one exemplary implementation, the automated test system fully utilizes hardware and software multi-thread multi-site capabilities.

It is appreciated that the present invention can be implemented in a variety of different ways. Features can be utilized in the testing of multiple independent devices in the same package (e.g., MCM/SIP). This would use separate test programs, running in parallel with combined binning. Features can also be utilized in the testing of PoP and can use combined binning or independent binning. The features can also be utilized in the testing of multi-chip wafers. In this scenario, instead of a single wafer containing all the same part, there are different devices on the wafer. For the case of a single site wafer prober, there can be rapid switching between test programs based on the die position. For multi-site probers, it is possible that several different test programs may be running in parallel, one on each site (although a single test program may be running in parallel on more than one site as well). This combination of test program to site mapping may change as the wafer is indexed. Tester automation software can use device type information from a wafer map to select the program for each site before each run in a mixed wafer scenario. These and other features are set forth in more detail in the following description.

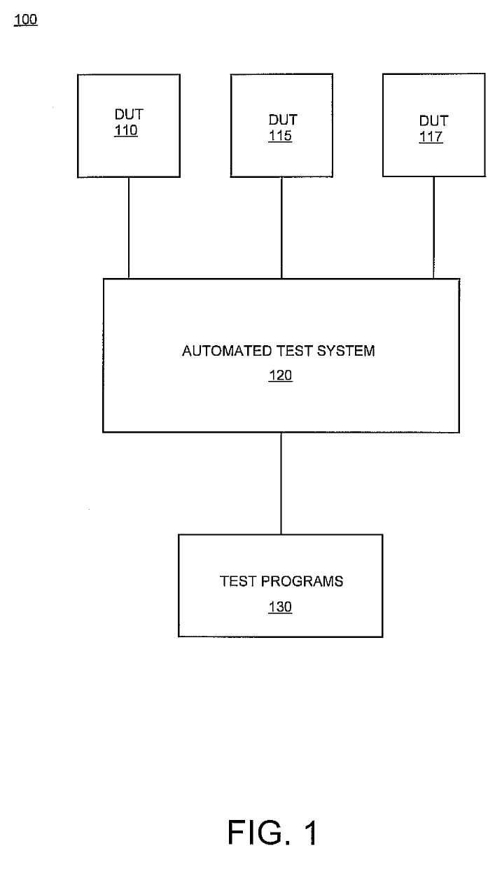

FIG. 1 is a block diagram of exemplary automated testing environment 100 in accordance with one embodiment of the present invention. Automated testing environment 100 includes devices under test (DUT) 110, 115 and 117, automated test system 120 and test programs 130. Devices under test 110, 115 and 117 are communicatively coupled to automated test system 120.

The components of automated testing environment 100 cooperatively operate to provide efficient testing of a device or devices under test. Device under test 110, device under test 115 and device under test 117 are the devices being tested. In one embodiment, device under test 110, device under test 115 and device under test 117 can be tested in parallel. Automated test system 120 coordinates and processes information received from device under test 110, device under test 115 and device under text 117.

It is appreciated that automated test system 120 facilitates efficient and effective testing including coordinating multi-test program processes. In one embodiment, automated test system 120 facilitates re-use of legacy or existing test programs to test different DUTs in the same package or test different DUTs in different packages in parallel. Automated test system 120 can also facilitate re-use of the test programs in wafer sort and final test activities. Multiple testing instruction sets can be loaded once and/or concurrently into automated test system 120 and coordinated for execution as a single program in accordance with one embodiment of the present invention.

It is appreciated that the present invention is readily implemented with a variety of different testing capabilities. Automated test system 120 can also facilitate parallel diagnostic activities. For example, parallel diagnosis of same and/or different instrument types. In one embodiment, automated test system 120 is also reconfigurable in the field in accordance with user supplied information (e.g., information related to user protocols, etc.).

In one embodiment, the automated test system 120 performs real time digital signal processing. In one embodiment, real time processing includes the time it takes to perform the digital signal processing in hardware of the automated test system 120. In one exemplary implementation, the real time processing can also be performed before the test signal data is loaded in a memory of the automated test system 120. In one embodiment, automated test system 120 is also reconfigurable in the field. In one exemplary implementation, automated test system 120 can receive configuration instructions and be configured in the field in accordance with user supplied information (e.g., information related to user protocols, etc.). Automated test system 120 can also facilitate synchronization with test data signals. In one embodiment, automated test system 120 receives a clock signal from a device under test and is a slave to the device under test.

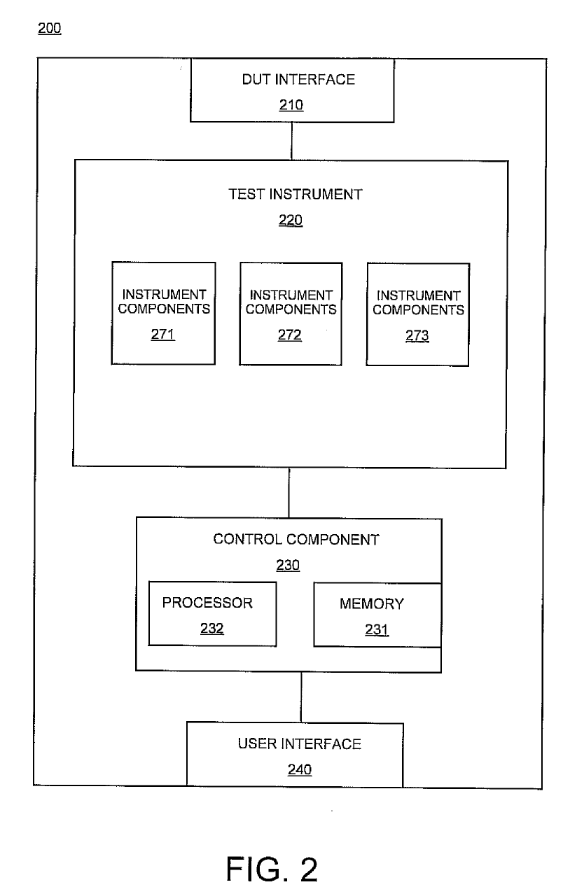

FIG. 2 is a block diagram of exemplary automated test system 200 in accordance with one embodiment of the present invention. In one embodiment, automated test system 200 can be utilized as automated test system 120. Automated test system 200 includes device under test (DUT) interface 210, test instrument 220, control component 230 and user interface 240. DUT interface 210 is coupled to test instrument 220 which is coupled to control component 230. Control component 230 is coupled to user interface 240.

The components of automated test system 200 cooperatively operate to perform automated test instrument functions. Device under test interface 210 interfaces with a device under test or a plurality of devices under test. Test instrument 220 performs testing activities associated with testing the DUTs. In one embodiment, test instrument 220 includes instrument components 271, 272 and 273 (e.g., digital signal instrument, analog signal instrument, mixed signal instrument, power supply instrument, radio frequency instrument, etc.). Control component 230 manages the test instrument 220 testing activities, including managing implementation of a plurality of test programs as a single coordinated program. User interface 240 enables interfacing with a user, including forwarding results of the testing to a user. In one embodiment, control component 230 includes a processor 232 and a memory 231 for implementing a multi-test coordinator.

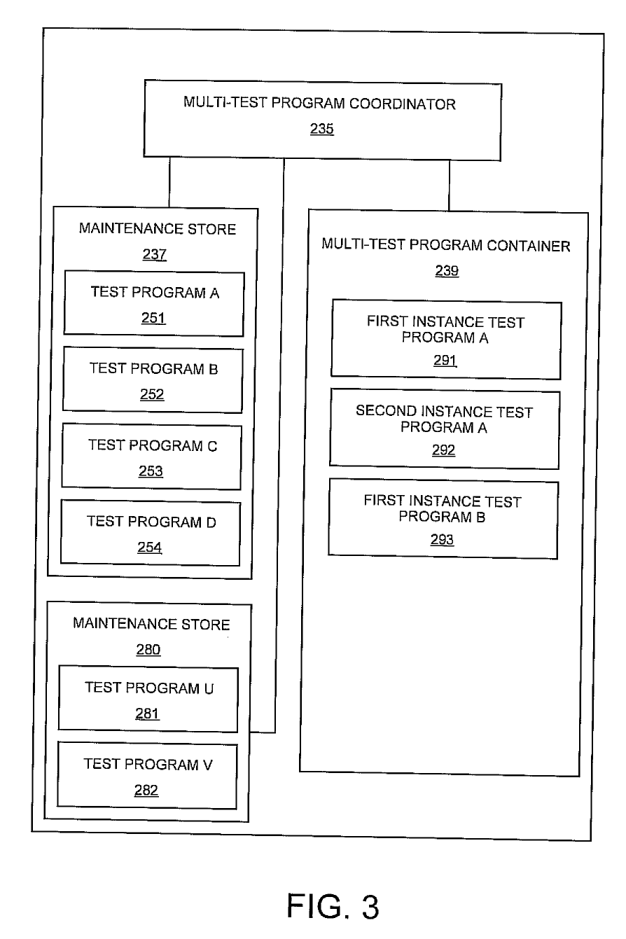

FIG. 3 is a block diagram of exemplary multi-test program components in accordance with one embodiment of the present invention. The components include, multi-test program coordinator 235, maintenance store 237 and multi-test program container 239. In one embodiment, multi-test program coordinator 235 enables more than one test program to be combined and executed as if it were a single test program. In one exemplary implementation, multi-test program coordinator 235 facilitates testing of MCM, SIP and MCW devices that contain different, independent sub-devices and/or different types of devices on a single substrate. Test programs can be developed for each sub-device or different type of device independently and subsequently used in a top level test program without modification. In one exemplary implementation, any other device that uses the same sub-device or type of device can reuse the same sub-device or different type of device test program.

The components cooperatively operate to coordinate testing of multiple devices. Multi-test program coordinator 235 manages the coordination of multiple test programs into a single testing process. In one embodiment, maintenance store 237 receives and stores multiple test programs. In one exemplary implementation, the test program modules associated with testing different types of devices are stored in maintenance store 237. For example, test program A 251 instructions for testing a type A device, test program B 252 instructions for testing a type B device, test program C 253 instructions for testing a type C device, and test program D 254 instructions for testing a type D device can be separately developed and maintained in maintenance store 237.

The multi-test program coordinator 235 determines the set of test programs to be utilized during test activities and coordinates loading of the corresponding test program instances in the multi-test program container 239 in a single process. Multi-test program container 239 stores instructions associated with a particular testing activity (e.g., touch down of testing probes or instruments on a site or particular set of devices). In one exemplary implementation, multi-test program coordinator 235 creates a first instance 291 of test program A 251, a second instance 292 of test program A 251 and a first instance 293 of test program B 252 and loads them in multi-test program container 239.

In one exemplary implementation, the maintenance store 237 and multi-test program container 239 can be implemented as a single container.

In one embodiment, a test system can include a variety of test instruments and the configuration of the test instruments can change. The present invention is readily adaptable for utilization in concurrent diagnostics of the test instruments themselves. With reference again to FIG. 3, multi-test program components can include a second maintenance store 280 for concurrent diagnostic test program U 281 and concurrent diagnostic test program V 282. Concurrent diagnostic test program U 281 can include instructions for testing a first test instrument (e.g., a digital signal test instrument, mixed signal test instrument, etc.) and concurrent diagnostic test program V 282 can include instructions for testing a second test instrument (e.g., a power supply test instrument, radio frequency mixed signal test instrument, etc.). Multi-test coordinator can coordinate and manage a single load of the concurrent diagnostic test programs. Multi-test coordinator can also coordinate and manage the creation of instances of concurrent diagnostic test programs in the multi-test program container 239 and testing of a plurality of test instruments in a group as a single test.

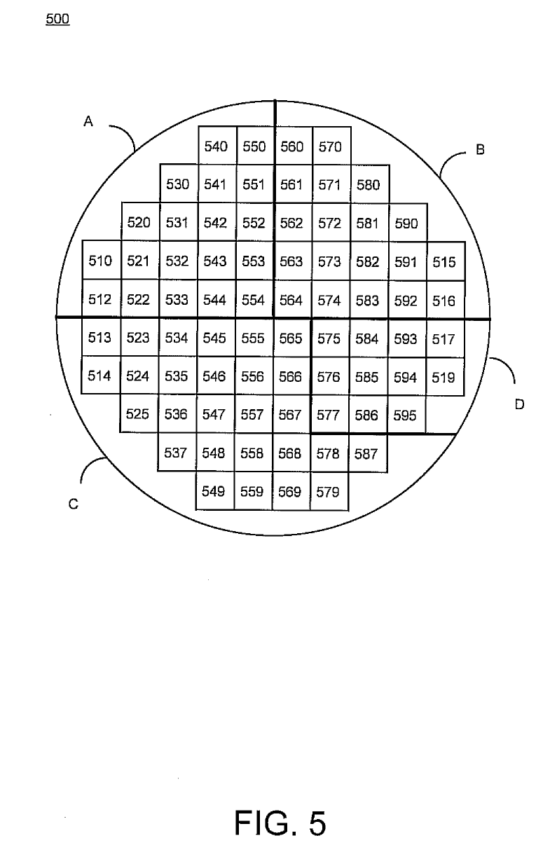

In one exemplary implementation, automated test system 200 is utilized to test multiple DUTs (e.g., DUTs 110, 115 and 117). The DUTs can be the same type, different type or combination of same and different. FIG. 5 is a block diagram of exemplary device die layout on a wafer 500 in accordance with one embodiment of the present invention. Wafer 500 is a multi-chip or device wafer including devices 510 through 595. The devices can be configured in groups or areas of the wafer. For example, device type A can be included in area A, device type B in area B, device type C in area C, and device type D in area D.

If the test instrument is going to “set” down straddling two different device types (e.g., device A and device B) or sites then multi-test program coordinator 235 retrieves the corresponding test program A module 251 and test program B module 252 and creates the appropriate amount of instances and puts them in multi-test program container 239. In one exemplary implementation, when the wafer is being tested and each die is considered a DUT, the test probes can cover three devices at a time. For example, the test probes can cover devices under test 110, 115 and 117 which can correspond to devices 552, 553, and 562. Multi-test program coordinator 235 retrieves the corresponding test program A module 251 and test program B module 252 and creates a first instance 291 of test program A 251 for testing device 552, a second instance 292 of test program A 251 for testing device 553 and a first instance 293 of test program B 252 for testing device 562 and loads them in multi-test program container 239.

In one embodiment, multiple test programs are run within the same process. The multi-test program coordinator 235 creates a separate namespace for each of the different test programs or sub-programs and coordinates utilization of multiple test programs or sub-programs even though multiple test programs or sub-programs can be using the same names for signals, test definition data blocks, etc. In one exemplary implementation, test system 200 supports utilization of a virtual machine with separate names spaces per test program. In one embodiment, the test programs are maintained in separate respective name spaces and the multi-test program module handles tracking data associated with corresponding names. For example, if test program A module 251 has a data block named XYZ and test program B module 252 also has a data block named XYZ, typically with different data contents, the multi-test program coordinator 235 handles coordination and tracking of each of the respective instances of data blocks XYZ. In one exemplary implementation, a single name space is used for Java class names.

The multi-test coordinator also handles the mapping of signal names in each of the test program instances to the correct tester resources and directs the different translations from signal names to tester resources for each device type program or sub-program and coordinates utilization of the same signal name in more than one test program or sub-program. For example, if the first instance of test program A 291 is going to direct testing of the DUT 552 via test instrument components 271 and if a type A device has 3 analog connections and 5 digital connections then the signal names used to refer to these device connections in the instance 291 of test program A are mapped to the corresponding 3 analog probe resources or instruments and 5 digital probe resources or instruments of test instrument components 271 that are connected to device 552. Similarly, if the second instance of test program A 292 is going to direct testing of the DUT 553 via test instrument components 272, then the signal names used to refer to these device connections in the instance 292 of test program A are mapped to the corresponding 3 analog probe resources or instruments and 5 digital probe resources or instruments of test instrument components 272 that are connected to device 553. If the first instance of test program B 293 is going to direct testing of the DUT 562 via test instrument components 271 and if a type B device has 3 digital connections then the signal names used to refer to these device connections in the instance 293 of test program B are mapped to the corresponding 3 digital probe resources or instruments of test instrument components 273 that are connected to device 562. In one exemplary implementation for a MCW, a particular sub-program can dynamically remap the hardware resources it uses from run to run.

In one embodiment, the multi-test program coordinator checks for conflicts between the test programs, for example instruments that cannot share resources between multiple test programs at the same time. In one embodiment, because of the way the hardware (e.g., test instruments) is mapped in the tester, each separate test program can use independent instruments or resources for tests that run in parallel. In other words, those instruments that cannot share resources (e.g., a pinslice) can be used for a single test program when running separate devices in parallel. Each test program can own the full instrument. In one exemplary implementation, some instruments (e.g., Device Power Supplies) have shareable instruments that may be split between test programs.

In one embodiment, device under test interface 210 includes a plurality of parallel interface ports for communicating with a plurality of devices under test in parallel (e.g., DUTs 110, 115 and 117). In one exemplary implementation, device under test interface 210 includes configurable multiple receiver signal drivers and multiple configurable transmit signal drivers. Interfacing with the device under test can also include a clock pin connection for receiving a clock signal from the device under test. In one embodiment, an interface between test instrument 220 and control component 230 is a fast speed interface. In one exemplary implementation, the interface between test instrument 220 and control component 230 also includes a direct backplane interface.

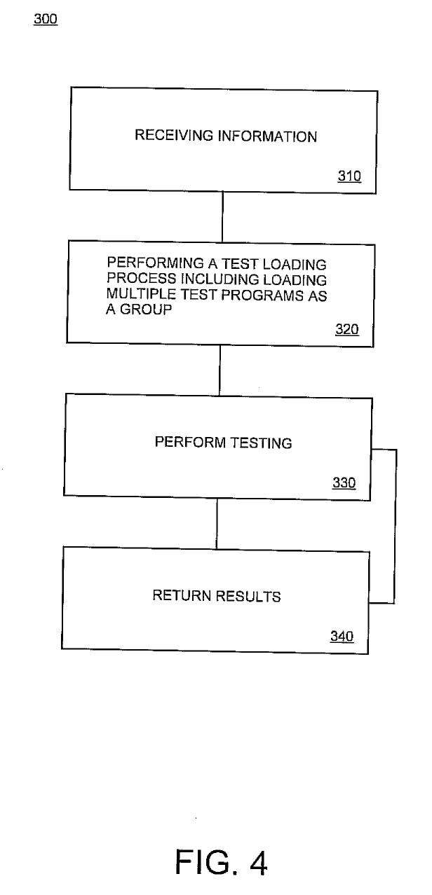

FIG. 4 is a flow chart of an exemplary testing method 300 in accordance with one embodiment of the present invention. In one embodiment, testing method 300 facilitates utilization of multiple independently created and maintained programs as a single program process. The independently created and maintained programs can be loaded in a single load process or at a single load time into a single container for device test. Again it is appreciated that the single container multi-program testing can be performed on multiple chip modules, packages and wafers. For example, testing method 300 can be utilized in testing of several independent devices in the same package (e.g., MCM/SIP/PoP) and/or multi-chip wafer (e.g., MCW) or combination of instruments to be diagnosed.

At block 310, information is received. In one embodiment, the information includes designation of multiple test programs to be included in a container. The multiple test programs can be independently created and maintained. The information can also include designation of a named sequence of tests or flow information (e.g., executable flow information, testing or other software operations sequence information, etc.).

At block 320, a test loading process is performed. In one embodiment, the test loading process includes loading multiple test programs as a group. In one exemplary implementation, test programs are loaded and combined under a single container (e.g., container 239) to be executed as a single test entity. Interfaces for users and interfaces for client applications are compatible and the single top level program is run similarly to other programs. In one embodiment, test programs are for single test functionality and are not changed in order to work in the test container. In one embodiment, test loading includes installing the constituent test programs serially and initializing them in parallel.

At block 330, testing is performed. It is appreciated that a variety of test procedures can be performed. In one embodiment, the test procedures are named sequence of tests. A test program may define several actions. In one exemplary implementation, the actions can include flows. In one embodiment, the top level program can include a mapping from the action names in the top level program to the action names in the sub-programs. Running an action in the top level program will run the mapped actions in the constituent test programs in parallel. If no mapping is provided for a particular action name, actions of the same name in the constituent test programs will be run. In one embodiment, hardware test resource loading processes (e.g., install flows, etc.) are run serially; and hardware test resource initialization and conflict checking (e.g., init flows, etc.) are run in parallel.

In block 340, test results are returned. In one embodiment, the returning test results includes supporting combined binning. Returning test results can also support independent binning. In one exemplary implementation, analysis is performed on the test results.

In one embodiment, the testing process 300 loops back to block 330 after block 340 for each area of the wafer that is being tested at a time. With reference again to FIG. 5 for example, the test probes can cover devices 531, 542, 532 and 543 and designated testing is performed on device type A. When the designated tests are performed (e.g., at block 330) and results are returned (e.g., at block 340), the probes can be moved to cover devices 552, 553, 562 and 563. The testing programs for the devices have already been loaded in block 320. The testing process loops back to block 330 device type A testing is performed for probes covering devices 552 and 553, and device type B testing is performed for probes covering devices 562 and 563.

### Description of a Software Framework in Accordance With One Embodiment of the Invention

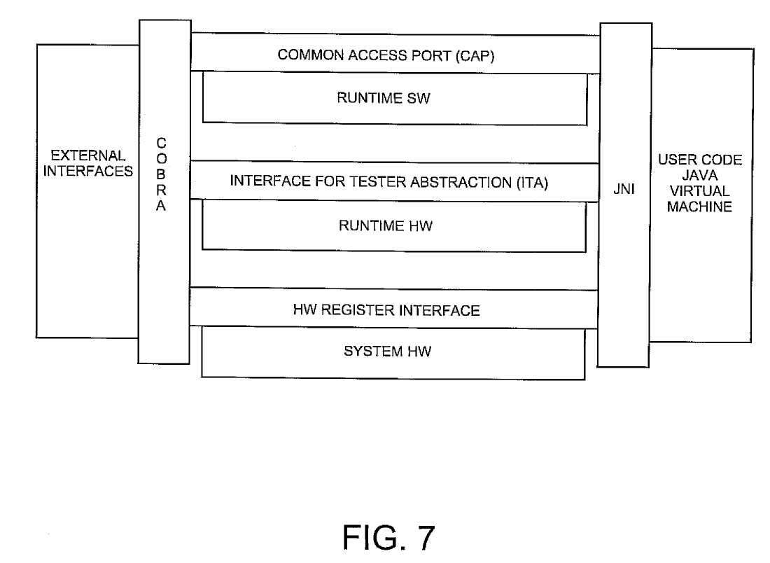

In one embodiment, features of the present invention are implemented as an extension of a software framework shown in FIG. 7. A similar framework is also described in U.S. Pat. No. 7,101,173, which is incorporated herein by this reference. The software framework runs test programs for testing different types of DUTs. The basic architecture of this framework comprises a distinct runtime software layer that is responsive to device or DUT terms and a distinct runtime hardware layer that is responsive to tester or ATE terms. The runtime software and hardware layers communicate via an interface for tester abstraction (ITA). The ITA provides the interface to translate between DUT terms and ATE terms. The framework also comprises a common access port (CAP) interface to access the runtime software area. Further, the framework comprises a common object broker architecture (CORBA) interface providing a communication path between various external interfaces and the runtime software and hardware layers and other parts of the framework not described here via the CAP and ITA interfaces and other interfaces not described here. The framework further comprises a user code module that provides the environment where user code (test templates) run. The test templates are divided into several categories including strategy control, binning control and test execution control. The user code module further includes standard test template implementations that can be customized. In one exemplary implementation, the user code area is provided in accordance with Java Virtual Machine (JVM) programming specifications, which interprets Java programs.

Aspects of the runtime software layer mentioned above include language objects that provide a platform for test definition, controller objects that operate on the language objects to define and control the test program and feature objects that implement capabilities that are not directly related to the language objects. The same patent also further describes certain aspects of the CAP interface mentioned above. This interface provides synchronous data access and asynchronous interaction, including a datalog interface that pushes data to designated outputs as it is created.

In this architecture, a test program for a particular type of DUT comprises the software framework discussed above together with certain Test Program Data that is specific to the type of DUT. The Test Program Data comprises test definition blocks, test templates and other types of data. The test definition blocks provide a way to define various parameters of the tests to be performed, for example “levels” and “timing”. They are loaded into language objects in the runtime software layer of the framework. Test templates provide instructions to execute a particular sequence of operations. They are loaded into the user code module of the framework. The term “Test Program” is commonly used to refer to the Test Program Data alone, and the term “Tester Operating System” is commonly used to refer to the software framework.

In one embodiment, the extension to the framework includes a multi-test program container object and a multi-program manager class utilized in the implementation of the multi-test program coordinator 235 and the multi-test program container 239 in the software framework shown in FIG. 7. In one exemplary implementation, the multi-test program container object describes the multiple test programs to be included in the container and actions to be implemented in association with the multiple test programs. The multi-program manager class facilitates runtime enhancements associated with executing the testing instructions in the multi-test program container.

In one embodiment, the multi-test program container object and the multi-program manager class are implemented partially in the runtime software (sw) layer, user code module and Interface for Tester Abstraction (ITA) layer. For example, portions of the multi-test program container object and the multi-program manager class that are associated with parts of the multi-test program coordinator 235 that are designed to be customizable are implemented as test templates in the user code module. It coordinates test programs (sets of test definition data blocks and test templates) that are loaded into the software framework. In one exemplary implementation, mapping between signal names used in the runtime software (sw) layer and tester resources in the runtime hardware (hw) layer and the system hardware (hw) is performed by the ITA under the control of the multi-test program coordinator 235. A signal name can be mapped to a plurality of tester resources to support multi-site testing. Each site can be enabled and disabled independently, and the ITA will perform requested operations in the runtime hardware layer on the resources belonging to enabled sites. The multi-test program container object and the multi-program manager class are further described below.

### Description of One Embodiment of a Test Container Object in Accordance With One Embodiment of the Invention

In one embodiment, the framework is utilized to implement a global test container object that encompasses multiple test programs. In one exemplary implementation, the framework is utilized to implement a global test container similar to multi-test program container 239 shown in FIG. 3. The test container is a test program for the combination of devices to be tested (e.g., MCM/SIP, PoP, MCW) or combination of instruments to be diagnosed. It coordinates the functionality of the separate multiple test programs that it contains. Because the test container is itself a test program, the usage of and interface to the tester is similar for testing multiple-device units as it is for testing single device types. A user can execute the test container top-level program. The test container top-level program is responsible for running the sub-programs as necessary and generating per-site results, so that a client application does not need to know that the loaded test program in fact can be a Multiple Container program. Individual test programs do not require manual changes from single test functionality in order to work in the test container. In one exemplary implementation, test programs are loaded/unloaded as a group. The top-level test program includes a test definition data block called a MultiTest Program block that references a plurality of legacy or existing test programs for the different DUT types.

In one exemplary implementation, an individual test program is referenced by the path of the directory where the test program data files are stored. In one embodiment, the following is XML code for one example of a

MultiTest Program Block:

```
<MultiTestProgram>
    <Type>COMBINED</Type>
    <TestProgram id=”1”>
        <Path>C:\testprograms\mc142\core</Path>
        <Action name=″Init″>
            <ActionRef>Initialize</ActionRef>
        </Action>
        <Action name=″Begin″>
            <ActionRef>Run</ActionRef>
        </Action>
    </TestProgram>
    <TestProgram id=”2”>
        <Path>C:\testprograms\audio\codec141</Path>
        <Action name=”Init”>
            <ActionRef>Validate</ActionRef>
            <ActionRef>InitWave</ActionRef>
            <ActionRef>Init</ActionRef>
        </Action>
        <Action name=”Begin”>
            <ActionRef>GO</ActionRef>
        </Action>
    </TestProgram>
</MultiTestProgram>
```

It is appreciated that there are a number of control features that can be implemented also. The second line defines the type of the overall test pass/fail result and the binning (COMBINED or INDIVIDUAL). Results and binning can be either combined (the binning result of the top level test program depends on the binning results of several constituent program instances, typical of MCM/SIP) or independent (typical of multi-chip wafer or concurrent diagnostics). Binning can also be either combined (e.g., to screen final good package) or independent (e.g., to allow the replacement of bad elements) in the PoP application. Lines 5 to 10 and lines 14 to 21 define the mapping for action names to run as discussed above.

In one embodiment, the global test container includes test templates for use in the actions of the top level test program. These include a MultiProgramLoader template and a MultiProgramExecute template. The MultiProgramLoader template reads the MultiTestProgram block and, if found, asks the software controller to validate it. The software controller loads the constituent programs specified in the block and initializes the MultiProgramManager class (discussed in further detail below). The MultiProgramExecute template runs the actions of the sub-programs that correspond to the action being executed in the current program. It gets the name of the current Action and looks up the matching “Action” section for each sub-program in the MultiTestProgram block. This gives the action(s) to run for each sub-program. In one embodiment, it then runs these actions in all the sub-programs. It is also appreciated that various coordination techniques for the multiple test programs can be implemented. In one embodiment, some actions such as installation flows are run in serial and other actions are run in parallel. Device testing (and other flows) can run a flow in each test program in parallel and then implement combined binning. In one exemplary implementation, a MultiProgramEndDevice template receives the results of each sub-program, reads the result type from the MultiTestProgram block and generates the combined or independent binning and other results for each site according to the result type. The MultiProgramEndDevice template receives and generates the results using the asynchronous datalog interface provided by the CAP.

In one embodiment, the top level test program has an Install action. The install action runs the MultiProgramLoader template first to load the constituent sub-programs and then runs the MultiProgram Execute template to run their installation actions. The top level test program also has an Init action that performs initialization. This checks for conflicts between the constituent programs and then runs the MultiProgramExecute template to run their initialization actions. The default top level program has a single “Begin” action for device testing, but users can create other actions to contain device tests. In one embodiment, the single “Begin” action can also contain top-level tests for those MCM or SIP devices that require overall initialization, for example to apply a shared power supply or to configure the device or partition the device electrically to allow the individual programs to run. Each device testing action runs the MultiProgramExecute template to execute the sub-program action(s) that correspond to the currently executing top-level action. The top level program also has an EndDevice action that the software framework runs automatically after each device testing action. This runs the MultiProgramEndDevice template to generate the top level binning results.

Recipe files (which can be used to override parts of the test program data) can be per test program and may include top-level setup to override test program level. In one exemplary implementation, the test container does not use any tester hardware resources, but would have software flows that can be executed.

In one embodiment, the global test container includes a combined “NameMap” block (mapping of test program names to tester hardware resources). This overrides the name maps in the constituent test programs. In one exemplary implementation, a default “top level” test program with standard flows, templates, etc., is provided so the user can just fill in a name map and MultiTestProgram blocks. Other aspects of the top level test program can be customized if required. A constituent test program can itself be a multi-test program for nested hierarchy.

In one embodiment, a global test container also includes features to support a multi-test program. Constituent test programs may use the same names for signals, blocks, etc., so there are separate name spaces for them. The Control Component 230 can have a method for determining which of the constituent test programs, including the test program container, is intended to be addressed. A unique ID can be maintained for each test program (e.g., based on the file directory path where it comes from). In one exemplary implementation, the Control Component 230 has a Common Access Port (CAP) programming interface comprising a plurality of different interface classes, which can be obtained from one another in a nested hierarchy starting from a top level interface object. A test program ID is specified when a top level interface object is obtained, and all objects derived from that top level object will communicate with that test program. The default behavior if no ID is specified is to access the top-level test program for compatibility.

In one embodiment, site management is included and multi-site testing is supported. Enabling a site creates an instance of a test program for the appropriate device type on that site. In one exemplary implementation of MCM/SIP testing each site refers to one module, and each sub-program tests a separate independent part of the module. The programs (e.g., top level, sub-programs, etc. ) have the same set of sites defined, but each sub-program uses a different set of tester resources for each site. The user can enable the sites for the modules to be tested. In one exemplary implementation, the specified sites can be enabled on all the programs together. The top-level program can combine the results from each sub-program and generate the overall pass/fail result and bin for the module, for each site.

In one exemplary implementation of site management for MCW testing each site refers to one die on the wafer, which may be a different device type each time a prober is indexed. Each sub-program tests one device type, and can be used for any of the sites. In one embodiment, each sub-program uses the same set of resources for each site, but only one sub-program will be executed on each site on each run. The user can enable the sites that each sub-program will test before each run. In practice this can be set automatically from information provided by the prober. In one exemplary implementation, this is done by a Test Session Program (TSP) that coordinates operation of the prober and tester to test a complete wafer or a Lot comprising multiple wafers. A check is made to ensure that a site is not enabled on more than one of the sub-programs. Each site will be enabled for the top-level program automatically if it is enabled on one of the sub-programs. The top-level program can copy the results for each site from the relevant sub-program that is enabled for that site, so that it generates the correct results for each site.

In one embodiment, a global test container includes an enhanced datalog. There can be separate datalog streams per test program independently of any separation of the datalog information per-site. There can also be a separate datalogging specification in each test program. In one exemplary implementation, a global (container level) enable/disable is provided.

In one embodiment, the automated test system 200 has various features to support a plurality of test programs. The notion of “current directory” can be maintained for each test program. Search paths are maintained per test program. Exceptions and errors identify the responsible test program. There can be support for the notion of a “global” exception. For example, exceptions that would affect running test programs (e.g., a serious hardware fault). In one exemplary implementation, an Abort function is system-wide and terminates execution of the whole group of test programs. In one exemplary implementation, the global or multi-test program container includes licensing features. For example, the whole combination of the test container and the constituent test programs only consumes one license for a software feature. Hardware exceptions can be mapped (by test instrument) to the test program(s) using that instrument and do not report to unaffected test programs. Arbitration for common hardware features (e.g., General Purpose Bus Interface (GPBI), Prober Handler Interface (PHI)) can be maintained. The test instrument can handle system-wide resources, for example triggers, properly among the concurrent test programs.

### Description of One Embodiment of a Multi-Test Program Manager Class in Accordance With One Embodiment of the Invention

In one embodiment, the software framework partitions program-specific data. A MultiProgramManager singleton class is provided to help with this. It maintains: (1) a list of loaded programs, and provides an interface to add entries to the list; (2) a unique integer ID for each loaded program (a client can use the ID to key its own collection(s) of per-program data); and (3) a mapping from operating system (OS) thread to the test program using that thread. In this manner a client can get the current program ID from the MultiProgramManager class without knowing which program it is servicing (e.g., the program name, etc.). Interfaces are provided to allow threads to be added and remapped.

In one embodiment, changes to existing code written to handle a single test program are only needed at the points where per-program data is stored. For example, it is not necessary for the class that manages test data to be duplicated per sub-program because only the test data needs to be stored separately for each program and the class can quickly and efficiently determine which storage to use when it is accessed by any sub-program.

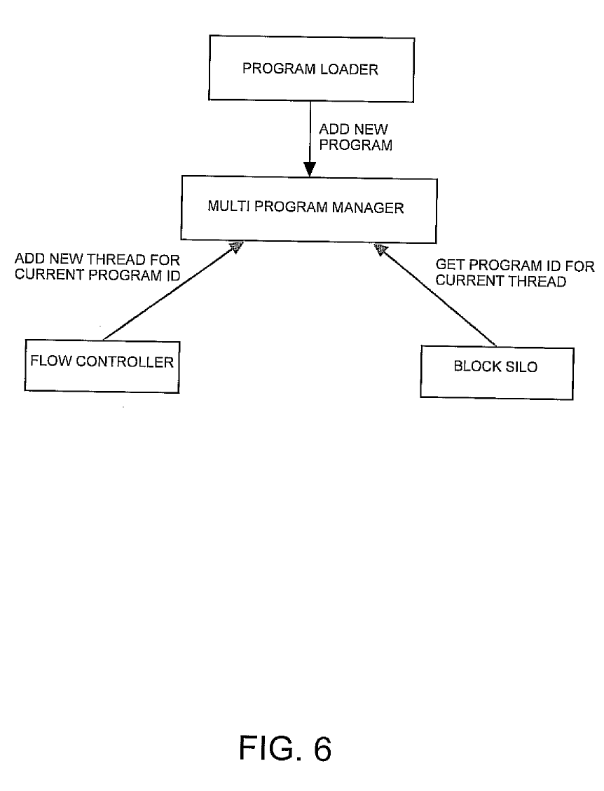

FIG. 6 is an exemplary block diagram showing a few of exemplary principle users of the class.

In one exemplary implementation, the present embodiment includes Class MultiProgramManager. This singleton class allows runtime threads to do the correct things without explicitly knowing which test program they are executing. For example, the signal to resource mapping classes in the ITA can store each sub-program's signal and resource information in a container keyed by the program ID (obtained from the combined NameMaps block). During execution, the current program ID can be quickly obtained from the MultiProgramManager class and used to locate the correct container for that test program.

It is appreciated the class contains a number of interfaces. The present embodiment can include an interface to return a reference to the MultiProgramManager singleton, creating it if necessary (e.g., static MultiProgramManager & reference ( );, etc.). The present embodiment can also include an interface to add the specified program and its ID to a singleton container (e.g., void addProgram (std:string const & programPath, int ProgramId), etc.). In one exemplary implementation, the top-level program does not need to be added and is guaranteed to have an ID of 0. In one embodiment, programPath uniquely identifies the program and is the full path to it. An exception can be thrown if the container already contains this program. In one exemplary implementation, the present add program interface is used just prior to loading the program.

In one embodiment, there is a register thread interface for registering the currently executing thread to the program given by programID (e g., void registerThread(int programId);, etc.). This is used whenever a new thread is created or when it is called from the new thread itself early in its life. For example, a registerThread is called from the Flow Controller when a new execution thread is created for the program. The Controller calls getProgramId before starting a new thread and passes the ID into the thread start-up method so that it can call registerThread( ). RegisterThread is also called from the CAP and ITA Corba layer whenever a new client request is serviced (a Corba servant can be randomly executed on any thread from the Corba pool).

In one embodiment, there is a program return interface for returning the program name for the currently executing programId (e.g., std: :string const & getProgramPath( );, etc.). This is used when the currently executing test program is to be specified in error messages etc.

In one embodiment, there is a program return interface that returns the program ID for the specified program name (e.g., int getProgramId (std: :string const & programPath);, etc.). This is used when a CAP servant is created for a program and it needs to know what the corresponding program ID is.

In one embodiment, there is a program return interface that returns the program ID for the currently executing thread (e.g., int getProgramId ( ); etc.). It returns 0 (the ID for the top-level program) if the current thread is not registered. This is used whenever runtime code needs to know which sub-program is executing so that it can access the correct data for this program, for example:
a) the Block Silo has a separate container of blocks for each sub-program;
b) the Equations system needs to be separate for each sub-program; or
c) the Signal to Resource mapping in the ITA keeps a separate map for each sub-program.

In one embodiment, there is a program return interface that returns the list of test program names in the container (e.g., void getPrograms (BasicArray<std: :string &>programPaths); etc.). This is provided for use by user interfaces when they need to present a selection list for the user.

### Description of a User Interface in Accordance With One Embodiment of the Present Invention

In one embodiment, various user interfaces enable convenient interaction and utilization of the “global” multi-test program container features. For example, an enhanced control tool can provide visual representation of the test container. When a user loads a Multiple Container program (one with a MultiTestProgram block), it automatically opens a new “Sub-Program Browser” window on the GUI to show the hierarchy of sub-programs. In one exemplary implementation, the browser is the main visual indication that the program has sub-programs. In one embodiment, the GUI includes a menu bar, tool bar, status bar, sub-program browser portion and tool portion. The sub-program browser portion includes a docked window showing test programs and how they are grouped together. The tools portion shows a selection of windows to show various aspects of a single test program. A user can select a top-level program or a sub-program in the sub-program browser. The content of the tool windows changes when the program selection changes. In one embodiment, when the sub-program selection is changed the control tool obtains a new top level CAP interface object with the appropriate program ID and passes it to the tool windows. The top level program is selected initially. In one exemplary implementation, the top-level program looks and behaves like a normal test program and can be used to run the group of sub-programs together. A variety of features including Save/Save As, BlockEditor, Datalog Control, Flow Run, and Data Analysis Tool run on the currently selected test program instance. The test program I/O can be combined from test programs. Preferences can be kept separate per test program. Sub tools scope on a single test program at a time. A visual indication of which test program is in scope can be provided.

In one embodiment, the GUI also includes tools that are started as separate processes, (e.g., a test tool for debugging a specific testing step of a test program, etc.). In one exemplary implementation, they do not change their displays when the program selection changes. The ID of the selected test program is added to the command line so that the tools can get a top level CAP area focused on the correct program.

Control Tool registers for certain runtime notifications from the programs (top-level and each sub-program), for example block change messages, so that it knows the modification state of the programs. When the program selection is changed, it updates the state of the “Save” button and the enable state of the sites. In one embodiment, other items can also be updated. When the test program is closed or Control Tool is quit, the check that is done to prompt the user to save the test program if it is modified is extended to save any of the programs that are modified. In one exemplary implementation, the save works independently on each test program. The Save on the top-level can be configured to automatically save modified sub-programs and “Save As” is made consistent, and the user specifies the directory for each program.

In one embodiment, the sub-program browser can show the modification state of each program (e.g., if it has been changed and needs saving, etc.). It can do this by registering for block change tool interaction messages from each program; and it is informed that a program has been saved by the Control Tool container, so that the state can be reset.

In one embodiment, a “New” button asks the user what kind of new program to create (e.g., an empty single test program, a multi-test program container program, etc.). After creating a new multi-test program container program, Control Tool sends a tool interaction message so that the Block Editor displays the MultiTestProgram block, ready for the user to fill it in.

In one embodiment, the user interfaces include an Operation Interface Control Tool (OICTool) and automation software (e.g., GEM/SECS interface) to control the tester in a production environment. There is no difference between executing a standard test program for a single DUT and a multi-test program, and the changes to the CAP and other programming interfaces are designed to be backwards-compatible so few changes are implemented to these applications.

Thus, the present invention facilitates efficient automated testing of devices. The present approach facilitates re-use of existing test programs to test different DUTs in the same package or test different DUTs in different packages in parallel facilitating conservation of time and effort. Users often extend a great deal of effort to test and characterize to validate test programs and changes to the test programs for inclusion in conventional multi-test approaches would involve significant revalidation, whereas the present embodiments facilitate coordination in a multi-test program container without changes to the test programs added to the container. The present approach also allows re-use of the same test program in wafer sort and final test. Additionally, this capability allows the diagnosing of different instrument types in parallel.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the Claims appended hereto and their equivalents.

What is claimed is:

1. A testing method comprising:
receiving information;
performing a test loading process including loading multiple test programs as a group;
performing testing; and
returning results.

2. A testing method of claim 1 wherein said executing includes:
running hardware test resource loading processes serially; and
running hardware test resource initialization and conflict checking in parallel.

3. A testing method of claim 1 wherein said returning results includes supporting combined binning.

4. A testing method of claim 1 wherein said returning results includes supporting independent binning.

5. A testing method of claim 1 wherein said multiple tests are executed as a single test.

6. A testing method of claim 1 wherein said executing testing includes testing Multi-Chip Module (MCM), Package-on-Package (PoP), System-In-Package (SIP), and Multi-Chip Wafer (MCW) devices that include different, independent sub devices on a single substrate.

7. A testing method of claim 1 wherein said loading includes coordinating loading of test program instances in a multi-test program container in a single process.

8. A testing method of claim 1 wherein said multiple test programs are loaded under a single container and executed as a single test entity, in which interfaces for users and interfaces for client applications are compatible and the single top level program is run similarly to other programs.

9. A testing method of claim 8 wherein said single container is utilized to test multiple chip modules, packages and wafers.

10. A testing method of claim 1 wherein said single container is utilized to perform concurrent diagnostics on test instruments.

11. A test system comprising:
an interface for interfacing with a device under test;
a test instrument for testing said device under test;
a test controller for managing testing activities of said test instrument, including managing implementation of a plurality of test programs loaded as a group; and
a user interface for interfacing with a user.

12. A test system of claim 11 wherein said test controller maintains the test programs separate respective name spaces and handles tracking data associated with corresponding names.

13. A test system of claim 11 wherein said plurality of test programs are loaded as a single container for device test of multiple chip modules, packages and wafers.

14. A test system of claim 11 wherein a global test container of said test controller includes separate datalog streams per test program.

15. A test system of claim 11 wherein said test controller fully utilizes hardware and software multi-thread multi-site capabilities.

16. A test system of claim 11 wherein said test controller supports a variety of applications including system-in-package testing, multi-chip module testing, multi-chip wafer testing and concurrent diagnostic testing.

17. A test loading method comprising:
receiving multiple test programs; and
combining said multiple test programs under a single container at a single load time.

18. A test loading method of claim 17 wherein said test programs are for single test functionality and are not changed in order to work in said single container.

19. A test loading method of claim 17 wherein said single container has software flows that can be executed without using any tester hardware resources.

20. A test loading method of claim 17 further comprising maintaining separate respective name spaces.

21. A test loading method of claim 17 wherein program-specific data is partitioned and a client can get a current program ID from a MultiProgramManager singleton class without knowing which program it is servicing, wherein the MultiProgramManager singleton class maintains:
(1) a list of loaded programs, and provides an interface to add entries to the list;
(2) a unique integer ID for each loaded program; and
(3) a mapping from operating system (OS) thread to the test program using that thread.
